(19) United States
(12) Patent Application Publication
(10) Pub. No.: US 2011/0037523 A1
(43) Pub. Date: Feb. 17, 2011

(54) CHARGE PUMP LINEARIZATION FOR DELTA-SIGMA FRACTIONAL-N PHASE LOCKED LOOPS

(75) Inventors: Per T. Roine, Oslo (NO); Jorg Ackermann, Akershus (NO)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/539,264

(22) Filed: Aug. 11, 2009

(51) Int. Cl. H03L 7/00

(52) U.S. Cl. 331/10

(57) ABSTRACT

A method and apparatus for linearizing a phase locked loop (PLL) are provided. To accomplish this, three separate signal (two feedback/one reference or two reference/one feedback) are applied to two phase/frequency detectors (PFDs). Either an edge of the one reference signal or one feedback signal is approximately equidistant between corresponding edges of the two feedback or two reference signals so that the PFDs can properly apply actuation signals to a charge pump that account for jitter. Thus, a more linear PLL is provided.

### TECHNICAL FIELD

The invention relates generally to phase locked loops (PLLs) and, more particularly, to charge pump linearization for delta-sigma fractional-N PLLs.

### BACKGROUND

For phase detectors used in PLLs, linearity can be important. Nonlinearities can lead to large reference spurs or increased in-band reference noise. Linearization techniques for PLLs, though, have been developed over the years. Two examples are: Temporiti, E. et al., “A 700-kHz Bandwidth ΣΔ Fractional Synthesizer With Spurs Compensation and Linearization Techniques for WCDMA Applications,” IEEE Journal of Solid-State Circuits, Vol. 39, September 2004 (“Temporiti”); and Pamarti, S. et al., “A Wideband 2.4-GHz Delta-Sigma Fractional-N PLL With 1-Mb/s In-Loop Modulation”, IEEE Journal of Solid-State Circuits, Vol. 39, January 2004 (“Pamarti”). Some other additional example of conventional PLLs can be found in U.S. Pat. Nos. 6,236,703; 6,960,947; 7,005,928; 7,142,025; U.S. Patent Pre-Grant Publ. No. 2004/0223576, and European Patent Appl. Nos. EP1458099; EP1458099; EP1458100; and EP 1458101. However, each technique and PLL design has drawbacks.

### SUMMARY

An embodiment of the present invention, accordingly, provides an apparatus. The apparatus comprises a first phase/frequency detector (PFD) that receives a first signal and a second signal; a second PFD that receives the second signal and a third signal wherein an edge of the second signal occurs about equidistantly between corresponding edges of the first and third signals; a charge pump having an up actuator and a down actuator, wherein the up actuator is coupled to the first PFD, and wherein the down actuator is coupled to the second PFD; a filter that is coupled to the charge pump; a voltage controlled oscillator (VCO) that is coupled to the filter, wherein the VCO generates an output signal; and a feedback loop that is coupled to the VCO, the first PFD, and the second PFD, wherein the feedback loop provides at least one of the third signal to the first and second PFDs or the first and third signals to the first and second PFDs.

In accordance with another embodiment of the present invention, the first and third signals are reference signals and the second signal is a feedback signal from the feedback loop.

In accordance with another embodiment of the present invention, the first and third signals are feedback signals from the feedback loop and the second signal is a reference signal.

In accordance with another embodiment of the present invention, the feedback loop further comprises: a divider that is coupled to the VCO, the first PFD, and the second PFD; and an error compensator that is coupled to the divider.

In accordance with another embodiment of the present invention, the error compensator further comprises a sigma-delta modulator.

In accordance with another embodiment of the present invention, the divider further comprises: a prescaler that is coupled to the VCO and the second PFD; and a plurality of D flip-flops coupled in series with one another, wherein the first D flip-flop of the plurality of D flip-flops coupled in series with one another is coupled to the prescaler, and wherein the last D flip-flop of the plurality of D flip-flops coupled in series with one another is coupled to the first PFD.

In accordance with another embodiment of the present invention, an apparatus is provided. The apparatus comprises a first PFD having an up output terminal, a down output terminal, a feedback input terminal, and a reference input terminal, wherein the feedback terminal of the first PFD receives a first signal, and wherein the reference terminal of the first PFD receives a reference signal; a second PFD having an up output terminal, a down output terminal, a feedback input terminal, and a reference input terminal, wherein the feedback terminal of the second PFD receives a second signal, and wherein the reference terminal of the second PFD receives the reference signal, and wherein an edge of the reference signal occurs about equidistantly between corresponding edges of the first and second signals; a charge pump having an up actuator and a down actuator, wherein the up actuator is coupled to up output terminal of the first PFD, and wherein the down actuator is coupled to the down output terminal of the second PFD; a filter that is coupled to the charge pump; a VCO that is coupled to the filter, wherein the VCO generates an output signal; and a feedback loop that is coupled to the VCO, the first PFD, and the second PFD, wherein the feedback loop provides at least one of the third signal to the first and second PFDs or the first and third signals to the first and second PFDs.

In accordance with another embodiment of the present invention, A method for linearizing a charge pump in a phase locked loop (PLL) is provided. The method comprising the steps of generating a first signal and a second signal, wherein the first signal and the second signal are out of phase; receiving a third signal and the first signal by a first PFD; receiving the third signal and the second signal by a second PFD, wherein an edge of the third signal occurs about equidistantly between corresponding edges of the first and second signals; outputting an up signal from the first PFD to an up actuator of a charge pump; and outputting a down signal from the second PFD to a down actuator of the charge pump.

In accordance with another embodiment of the present invention, the step of generating further comprises: generating the first signal from an output signal; and delaying the first divided signal to generate the second divided signal.

In accordance with another embodiment of the present invention, the method further comprises the steps of: filtering a signal output from the charge pump; and generating the output signal with a VCO from the filtered signal.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B are examples of block diagrams depicting a PLL in accordance with an embodiment of the present invention;

FIG. 2 is a block diagram of the divider of FIG. 1A; and

FIGS. 3A and 3B are timing diagrams for the PLLs of FIGS. 1A and 1B.

### DETAILED DESCRIPTION

Refer now to the drawings wherein depicted elements are, for the sake of clarity, not necessarily shown to scale and wherein like or similar elements are designated by the same reference numeral through the several views.

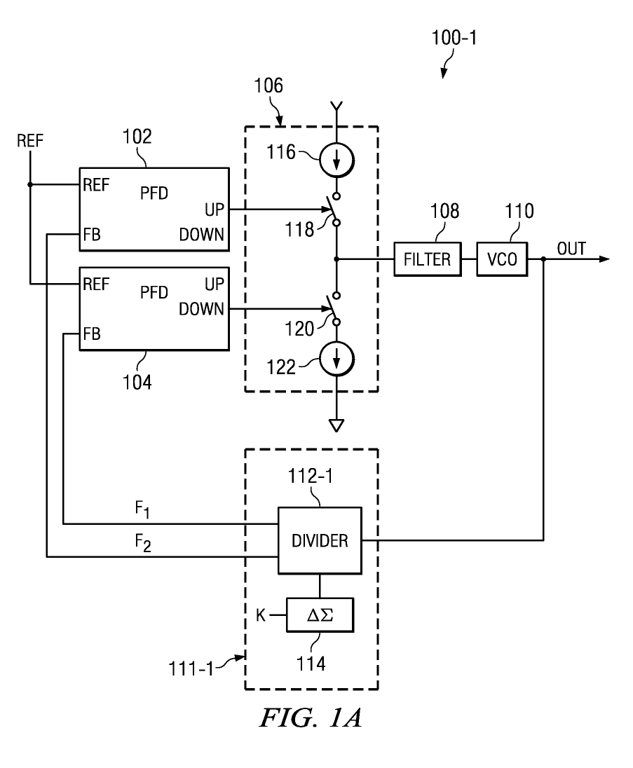

Referring to FIGS. 1A and 1B of the drawings, the reference numerals 100-1 and 100-2 generally designate PLLs in accordance with an embodiment of the present invention. The PLLs 100-1 and 100-2 generally comprise a phase/frequency detectors (PFD) 102 and 104, a charge pump 106, a filter 108, and a voltage controlled oscillator (VCO) 110. A different between PLLs 100-1 and 100-2 exists in the feedback loop 111-1 and 111-2, where divider 112-1 provides two feedback signals and divider 112-1 provides one feedback signal.

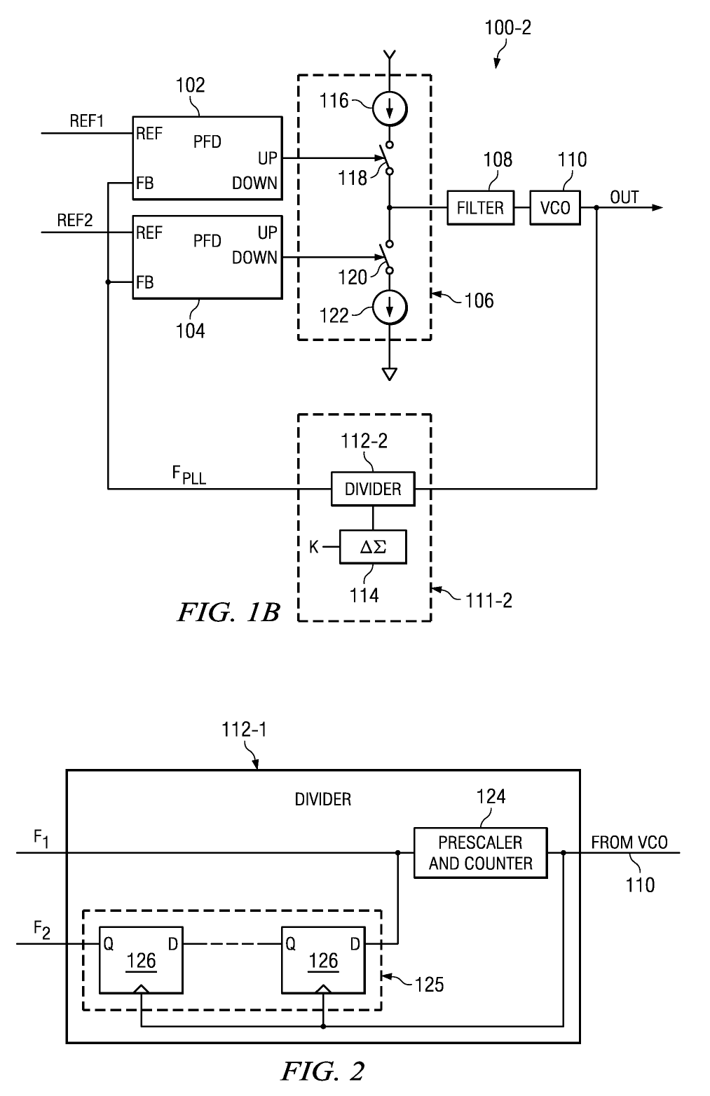

Turning first to FIG. 1A, the VCO 110 generates an output signal OUT, which is output to other external circuitry and to the feedback loop 111-1. The feedback loop 111-1 is generally comprised of a divider 112-1 and a phase loop error compensator or sigma-delta modulator 114. Divider 112-1 can be implemented using a conventional programmable divider having a multi-modulus prescaler followed by an A/M counter 124 (as can be seen in FIG. 2) for generating signal F₁ and a delay chain 125 for generating signal F₂. Preferably, the delay chain 125 is comprised of a plurality of D-type flip-flops 126 arranged in series and clocked on the output signal OUT from the VCO 110, so that signal F₂ is essentially a delayed copy of signal F₁. Additionally, for reduced noise/jitter, signal F₁ can be retimed by a flip-flop that is clocked by the VCO 110 directly or by a signal in the prescaler 124. Moreover, the compensator 114 receives signal F₁ and provides a correction signal K to the precaler 124.

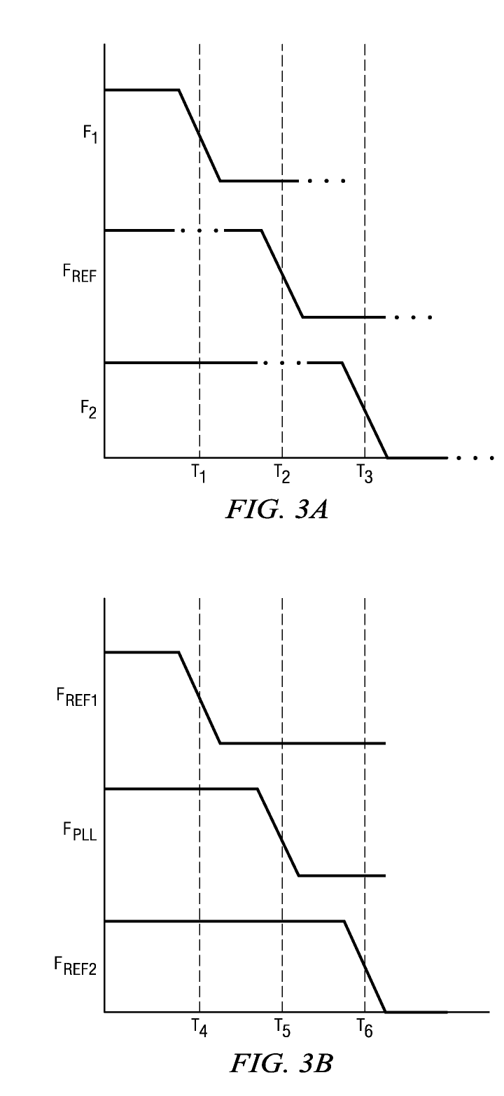

These signals F₁ and F₂ are then, preferably, used to achieve a lock condition in the PLL 100-1. Signals F₁ and F₂ are compared to a reference signal REF in PFDs 104 and 102 (respectively). Ideally, when the PLL 100-1 is in a locked condition, an edge of the reference voltage REF will occur in the about in middle or approximately equidistantly between the two corresponding edges of signals F₁ and F₂ (as shown in FIG. 3A). In other words and as seen in FIG. 3A, the time between T₁ and T₂ is approximately equal to the time between T₂ and T₃. An up signal can then be provided to the up actuator or switch 118 of the charge pump 106 from the up output terminal of PFD 102, while a down signal can be provided to the down actuator or switch 120 of charge pump 106 from the down output terminal of PFD 104. By having the signal REF being between signal F₁ and F₂, the charge pump 106 can output a positive current from current source 116 during the time from an edge of signal F₁ to an edge of the reference signal REF and a negative current from the current source 122 during the time from an edge of the reference signal REF to an edge of the signal F₂. The charge pump 106 can then output a signal to filter 108, which provides a filtered signal to the VCO 110.

Under these circumstances, if the effective positive and negative currents differ in magnitude, the edge of the reference signal REF will be offset from the middle. Any phase error or jitter from the VCO 110 will cause corresponding edges of signals F₁ and F₂ to move by about the same amount in the same direction. In other words, if pulse width for the up signal changes by ΔT, then the pulse width of the down signal changes by −ΔT. Assuming a generally constant positive and negative current, a charge contribution would be:

|I_{U}|·ΔT−|I_{DOWN}|·(−ΔT)=(|I_{UP}|+|I_{DOWN}|)·ΔT (1)

Thus, the inequalities between positive and negative current can be cancelled or significantly reduced. Additionally, the PLL 100-1 allows the charge pump current to effectively be doubled compared to traditional designs.

It should also noted that the linearization and doubled effective charge pump current only occurs when the phase error is small enough to maintain an edge of the reference signal REF between the corresponding edges of the signals F₁ and F₂. Outside this phase error range, the effective charge pump current is either |I_{UP}| or |I_{DOWN}|. Therefore, the delay between signals F₁ and F₂ should be chosen to be larger than the largest or smallest value of the accumulated jitter that can be caused by the delta-sigma modulator 114.

Alternatively, as can be seen in FIG. 1B, divider 112-2 can provide a single feedback signal F_{PLL} to each of PFDs 102 and 104, and two separate reference signals REF1 and REF2 can be provided to PFDs 102 and 104. In this configuration, an edge of signal F_{PLL} is approximately equidistantly between corresponding edges of signals REF1 and REF2 (as can be seen in FIG. 3B where the span between times T₄ and T₅ is about the same as the span between times T₅ and T₆) to achieve substantially the same result as in PLL 100-1.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a first phase/frequency detector (PFD) that receives a first signal and a second signal;
a second PFD that receives the second signal and a third signal wherein an edge of the second signal occurs about equidistantly between corresponding edges of the first and third signals;
a charge pump having an up actuator and a down actuator, wherein the up actuator is coupled to the first PFD, and wherein the down actuator is coupled to the second PFD;
a filter that is coupled to the charge pump;
a voltage controlled oscillator (VCO) that is coupled to the filter, wherein the VCO generates an output signal; and
a feedback loop that is coupled to the VCO, the first PFD, and the second PFD, wherein the feedback loop provides at least one of the third signal to the first and second PFDs or the first and third signals to the first and second PFDs.

2. The apparatus of claim 1, wherein the first and third signals are reference signals and the second signal is a feedback signal from the feedback loop.

3. The apparatus of claim 1, wherein the first and third signals are feedback signals from the feedback loop and the second signal is a reference signal.

4. The apparatus of claim 1, wherein the feedback loop further comprises:
a divider that is coupled to the VCO, the first PFD, and the second PFD; and
an error compensator that is coupled to the divider.

5. The apparatus of claim 4, wherein the error compensator further comprises a sigma-delta modulator.

6. The apparatus of claim 4, wherein the divider further comprises:
a prescaler that is coupled to the VCO and the second PFD; and
a plurality of D flip-flops coupled in series with one another, wherein the first D flip-flop of the plurality of D flip-flops coupled in series with one another is coupled to the prescaler, and wherein the last D flip-flop of the plurality of D flip-flops coupled in series with one another is coupled to the first PFD.

7. An apparatus comprising:
a first PFD having an up output terminal, a down output terminal, a feedback input terminal, and a reference input terminal, wherein the feedback terminal of the first PFD receives a first signal, and wherein the reference terminal of the first PFD receives a reference signal;
a second PFD having an up output terminal, a down output terminal, a feedback input terminal, and a reference input terminal, wherein the feedback terminal of the second PFD receives a second signal, and wherein the reference terminal of the second PFD receives the reference signal, and wherein an edge of the reference signal occurs about equidistantly between corresponding edges of the first and second signals;
a charge pump having an up actuator and a down actuator, wherein the up actuator is coupled to up output terminal of the first PFD, and wherein the down actuator is coupled to the down output terminal of the second PFD;
a filter that is coupled to the charge pump;
a VCO that is coupled to the filter, wherein the VCO generates an output signal; and
a feedback loop that is coupled to the VCO, the first PFD, and the second PFD, wherein the feedback loop provides at least one of the third signal to the first and second PFDs or the first and third signals to the first and second PFDs.

8. The apparatus of claim 7, wherein the feedback loop further comprises:
a divider that is coupled to the VCO, the first PFD, and the second PFD; and
an error compensator that is coupled to the divider.

9. The apparatus of claim 8, wherein the error compensator further comprises a sigma-delta modulator.

10. The apparatus of claim 8, wherein the divider further comprises:
a prescaler that is coupled to the VCO and the feedback terminal of the second PFD; and
a plurality of D flip-flops coupled in series with one another, wherein the first D flip-flop of the plurality of D flip-flops coupled in series with one another is coupled to the prescaler, and wherein the last D flip-flop of the plurality of D flip-flops coupled in series with one another is coupled to the feedback terminal of the first PFD.

11. A method for linearizing a charge pump in a phase locked loop (PLL), the method comprising the steps of:
generating a first signal and a second signal, wherein the first signal and the second signal are out of phase;
receiving a third signal and the first signal by a first PFD;
receiving the third signal and the second signal by a second PFD, wherein an edge of the third signal occurs about equidistantly between corresponding edges of the first and second signals;
outputting an up signal from the first PFD to an up actuator of a charge pump; and
outputting a down signal from the second PFD to a down actuator of the charge pump.

12. The method of claim 11, wherein the step of generating further comprises:
generating the first signal from an output signal; and
delaying the first divided signal to generate the second divided signal.

13. The method of claim 12, wherein the method further comprises the steps of:
filtering a signal output from the charge pump; and
generating the output signal with a VCO from the filtered signal.

14. The method of claim 11, wherein the first and second signals are reference signals and the third signal is a feedback signal from a feedback loop.

15. The apparatus of claim 11, wherein the first and second signals are feedback signals from a feedback loop and the third signal is a reference signal.
